(19) United States
(12) Patent Application Publication
(10) Pub. No.: US 2005/0145856 A1
(43) Pub. Date: Jul. 7, 2005

(54) Gallium nitride semiconductor device and method of producing the same

(75) Inventors: Tsunenori Asatsuma, Kanagawa (JP); Hiroshi Nakajima, Kanagawa (JP); Osamu Goto, Miyagi (JP); Tsuyoshi Tojo, Kanagawa (JP)

Correspondence Address: ROBERT J. DEPKE LEWIS T. STEADMAN;TREXLER, BUSHNELL, GLANGLORGI, BLACKSTONE & MARR,, 105 WEST ADAMS STREET, SUITE 3600, CHICAGO, IL, 60603-6299, US

(73) Assignee: Sony Corporation

(21) Appl. No.: 11/045,652

(22) Filed: Jan. 28, 2005

Related U.S. Application Data
(62) Division of application No. 10/445,601, filed on May 27, 2003.

(30) Foreign Application Priority Data
May 29, 2002 (JP) JP2002-155507

(51) Int. Cl. H01L 21/00; H01L 27/15; H01L 29/26; H01L 31/12; H01L 33/00; H01L 29/24

(52) U.S. Cl. 257/79; 438/22

(57) ABSTRACT

The present invention provides a gallium nitride semiconductor device including an electrode composed of a metallic film on an underlying gallium nitride compound semiconductor layer. The gallium nitride semiconductor device is characterized in that recessed portions are present dispersely over the whole surface area of the underlying compound semiconductor layer in contact with the electrode metallic film in such a manner that at least two recessed portions having a depth greater than the lattice constant of crystals constituting the underlying compound semiconductor layer are present on a width direction line in any 1 μm width region of the whole surface area.

### BACKGROUND OF THE INVENTION

The present invention relates to a gallium nitride semiconductor device and a method of producing the same, and more particularly to a gallium nitride semiconductor device having a low operating voltage and high reliability and a method of producing the same.

Semiconductors based on a Group III-V gallium nitride compound such as GaN, GaInN, AlGaInN, etc. has a band gap ranging from 2.8 to 6.8 eV, so that they are paid attention to as a material for a semiconductor light-emitting device capable of emitting light in the range from red color to UV region.

As a gallium nitride semiconductor device including a Group III-V gallium nitride compound semiconductor as a component element, there have been developed and put to practical use, for example, blue or green light-emitting diodes (LEDs) and a GaN semiconductor laser device with oscillation in a purple region of about 405 nm.

Here, referring to FIG. 2, the constitution of the GaN semiconductor laser device will be described. FIG. 2 is a sectional view showing the constitution of the GaN semiconductor laser device.

As shown in FIG. 2, the GaN semiconductor laser device 10 includes a sapphire substrate 12, a GaN-ELO (Gan Epitaxially Lateral Overgrowth) structure layer 14 formed on the sapphire substrate 12 by a lateral growth method, and a laminate structure constituting of an n-type GaN contact layer 16, an n-type AlGaN clad layer 18, an n-type GaN guide layer 20, an active layer 22 having a GaInN multiple quantum well (MQW) structure, a p-type GaN guide layer 24, a p-type AlGaN clad layer 26, and a p-type GaN contact layer 28 sequentially formed on the GaN-ELO structure layer 14 by a metallo-organic chemical vapor deposition (MOCVD) method.

An upper layer of the p-AlGaN clad layer 26 and the p-GaN contact layer 28 are formed as stripe form ridges 30 located between a seed crystal portion and an association portion of the GaN-ELO structure layer 14.

Further, the remaining layer of the p-AlGaN clad layer 26, the p-GaN light guide layer 24, the active layer 22, the n-GaN light guide layer 20, the n-AlGaN clad layer 18, and an upper layer of the n-GaN contact layer 16 are formed as mesas 32 parallel to the ridges 30.

The upper side of the p-GaN contact layer 28 is opened, and an SiO₂ film 34 is formed on both side surfaces of the ridges 30 and on the remaining layer of the p-AlGaN clad layer 26.

A p-side electrode 36 composed of a Pd/Pt/Au laminate metallic film is provided on the p-GaN contact layer 28, and an n-side electrode 38 composed of a Ti/Pt/Au laminate metallic film is provided on the n-GaN contact layer 16.

Next, a conventional method of producing the above-mentioned semiconductor laser device 10 by an MOCVD method will be described.

Ammonia (NH₃) is used as a nitrogen source, whereas trimethylgallium (TMG), trimethylaluminum (TMA), and trimethylindium (TMI) are used respectively as materials for Group III metals, i.e., Ga, Al, and In.

A dopant for the n-type is Si, whereas a dopant for the p-type is Mg, and monosilane (SiH₄) and bis-methylcyclopentadienylmagnesium (MeCp₂Mg) are used respectively as materials for the dopants Si and Mg.

Incidentally, the materials such as the material for nitrogen and the materials for the Group III metals are not limited to the above-mentioned ones.

First, the GaN-ELO structure layer 14 is formed on the sapphire substrate 12 by application of the lateral growth method. Next, the n-type GaN contact layer 16, the n-type AlGaN clad layer 18, the n-type GaN guide layer 20, and the active layer 22 composed of the GaInN multiple quantum well (MQW) structure are sequentially grown on the GaN-ELO structure layer 14 by the MOCVD method.

Further, the p-type GaN guide layer 24, the p-type AlGaN clad layer 26, and the p-type GaN layer 28 are sequentially grown.

In forming the laminate structure, at the time of growing the p-type GaN layer 28 after growing the p-type AlGaN clad layer 26, first, the p-type GaN layer 28 is grown at a substrate temperature of about 1000° C.

Next, when the growth of the p-type GaN layer 28 is finished, supply of TMG and MeCp₂Mg is stopped, while supply of NH₃ gas is continued, and under this condition, the substrate temperature is lowered to a temperature around room temperature, thereby finishing the formation of the laminate structure.

Next, the ridges 30 and the mesas 32 are formed, and the SiO₂ film 34 is formed. Subsequently, the SiO₂ film 34 is provided with openings, and the p-side electrode 36 and the n-side electrode 38 are formed.

Further, cleavage is conducted to obtain chips, whereby the GaN semiconductor laser devices 10 can be produced.

However, the above-mentioned conventional GaN semiconductor device has the problem that the operating voltage is high and, in some cases, an operating voltage of not less than 7.0 V has been needed at the time of injecting a current of 50 mA, for example.

Where the operating voltage is high, it is difficult to reduce power consumption, and it imposes restrictions on enhancement of reliability and prolongation of life. Further, restricted by the supply voltage from a power source, it is difficult to reduce size and weight, resulting in that it is difficult to enhance portability of the apparatus using the semiconductor laser device as a light source.

In addition, in the GaN semiconductor laser device, stripe form electrodes having a width of about 3 μm, for example, are formed on the p-type contact layer as p-side electrodes, for lowering the threshold current and enhancing the efficiency of injected current to light output. In this case, the metallic layer constituting the p-side electrodes is liable to be exfoliated from the p-type contact layer, and once exfoliation has occurred even partly, the contact resistance between the p-side electrodes and the p-type contact layer is largely increased even if the exfoliation region is on the micrometer order in size.

Furthermore, where the exfoliation has occurred, light emission characteristics may be lowered due to non-uniformity of current injection, power consumption may be increased due to a rise in operating voltage, and, in an extreme case, laser oscillation may cease. Accordingly, it is difficult to enhance the reliability of the GaN semiconductor laser device.

While the GaN semiconductor laser device is described as an example in the above description, these problems apply in general to gallium nitride semiconductor devices including light-emitting diodes, electronic devices and the like.

### SUMMARY OF THE INVENTION

Accordingly, it is an object of the present invention to provide a gallium nitride semiconductor device having a low operating voltage and high reliability and a method of producing the same.

One of the causes of the high operating voltage of the GaN semiconductor device lies in that the contact resistance of the p-side electrodes is high due to the characteristics of the p-type compound semiconductor layer, which is lower in carrier density and mobility and higher in resistance than the n-type compound semiconductor layer.

It is technically difficult to lower the electric resistance of the p-type semiconductor layer. In order to solve the above-mentioned problem, the present inventors, in search of other solutions than the lowering of the electric resistance of the p-type semiconductor layer itself, observed the outermost surface morphology (rugged state) of the p-type GaN contact layer, which is the underlying for the metallic film constituting the p-side electrodes, under an atomic force microscope (AFM). As a result of the observation, they have found out that the surface of the p-type GaN contact layer is comparatively flat although terrace-type flat surfaces and step structures are present in the surface, as shown in FIG. 4. FIG. 4 is a diagram showing the outermost surface morphology of the p-type GaN contact layer, which is the underlying film for the p-side electrode metallic film in a conventional GaN semiconductor laser device. Incidentally, FIG. 4 is a copy from a photograph of FIG. 3, and the original photograph has been separately submitted to the Japanese Patent Office as reference photograph.

Further, upon examination of a section of a surface portion of the p-type GaN contact layer along line B-B′ of FIG. 4, it has been found that there is comparatively few rugged portions in the surface, there is no recessed portions on the nanometer order, and the steps of rugged portions are about 0.5 nm in height, as shown in FIG. 5. The value of 0.5 nm of the steps is very approximate to the lattice constant c of GaN, AlN, and InN. In addition, the standard deviation (Rms) of the ruggedness (height) over the whole area of the surface was 0.186 nm. FIG. 5 is a sectional view of a surface layer portion of the p-type GaN contact layer along line B-B′ of FIG. 4, in the conventional GaN semiconductor laser device.

Where the surface has comparatively few rugged portions and the steps are small in height, the adhesion property between the p-side electrode metallic film and the underlying film is poor, the contact area therebetween is small, and the attachment property is also poor.

In view of this, the present inventors got an idea of providing the underlying film for the p-side electrode metallic film with ruggedness. Then, the present inventors paid attention to the fact that the underlying film can be provided with ruggedness by growing a re-epitaxial layer dispersely and microscopically on the underlying film in a temperature fall process after growth of the underlying film, and conducted the following experiments.

### Experimental Examples

In the present experimental example, at the time of forming the p-type GaN contact layer 28 of the semiconductor laser device 10 mentioned above, the GaN layer was epitaxially grown by the MOCVD method at a substrate temperature of 1000° C. to form the P-type GaN contact layer 28 in a predetermined film thickness, in the same manner as in the related art.

Subsequently, while introducing TMG, TMI, NH₃ gas, and MeCp₂Mg, the substrate temperature was lowered to about 700° C. over a period of 1 to 2 min, and the temperature of 700° C. was maintained for 5 to 60 sec.

Next, the supply of TMG, TMI, and MeCp₂Mg was stopped, and the substrate temperature was lowered to room temperature while introducing only the NH₃ gas.

The outermost surface morphology of the p-type GaN contact layer 28 formed as above was observed under an AFM. Upon the observation, the followings were found.

(1) As shown in FIG. 7, groove form recessed portions 40 having a groove width of 3 to 100 nm and a depth larger than the lattice constant of GaN crystal are present in an irregular network form at an interval of 5 to 300 nm in the whole area of the surface of the p-type GaN contact layer 28. FIG. 7 is a diagram showing the outermost surface morphology of the p-type GaN contact layer obtained in the experimental example. Incidentally, FIG. 7 is a copy of a photograph of FIG. 6, and the original photograph has been separately submitted to the Japanese Patent Office as reference photograph.

(2) From the results of measurement under the AFM, a section along line A-A′ in FIG. 7 was drawn, upon which a sectional configuration as shown in FIG. 8 was obtained. FIG. 8 is a sectional view of a surface layer portion of the p-type GaN contact layer obtained in the experimental example, taken along line A-A′ of FIG. 7.

From FIG. 8, it was found that a typical value of the size of the step in the ruggedness, i.e., the height difference (step) between the crest portion of a projected portion 42 constituting the ruggedness and the bottom portion of a recessed portion 44 adjacent to the projected portion 42 is 1 to 2 nm. Since the lattice constants “c” of wurtzite type GaN, AlN, and InN crystals are about 0.519 nm, about 0.498 nm, and about 0.576 nm, respectively, it is clear that the step in the ruggedness is greater than the lattice constants.

In addition, the rugged portions are present dispersely over the whole area of the surface of the p-type GaN contact layer 28 so that at least two rugged portions are located on a width direction line in any 1 μm width region of the whole surface area.

(3) In FIG. 7 showing the results of measurement obtained by scanning a 1 μm square area, the standard deviation (Rms) of the ruggedness (height) was 0.466 nm. Besides, upon scanning (measuring) the whole surface area of the p-type GaN contact layer 28, it was found that Rms (standard deviation of height) of the ruggedness was greater than 0.25 nm, for each ruggedness present in any 1 μm square region of the whole surface area.

From the experimental results as above, it was confirmed that, by varying the conditions of the temperature lowering process of lowering the temperature from a predetermined temperature to room temperature after forming the p-type GaN contact layer 28 in a predetermined film thickness at the predetermined temperature, the rugged portions with steps greater than the lattice constant of the GaN crystals are formed dispersely over the whole surface area.

When a p-side electrode metallic film was formed on the p-type GaN contact layer 28 having the rugged portions in its surface, it was confirmed that the adhesion property between the metallic film and the p-type GaN contact layer 28 is enhanced, and the contact area is conspicuously enlarged, whereby the contact resistance was largely reduced. It was also confirmed that since the metallic film enters into the recessed portions to achieve firm attachment of the metallic film and the p-type GaN contact layer 28 to each other, the problem of exfoliation of the p-side electrode metallic film from the p-type GaN contact layer 28 is obviated.

In order to attain the above object, based on the above experimental results, according to the present invention, there is provided a gallium nitride semiconductor device including an electrode composed of a metallic film on an underlying gallium nitride compound semiconductor layer (hereinafter referred to as underlying compound semiconductor layer), wherein

recessed portions are present dispersely over the whole surface area of the underlying compound semiconductor layer in contact with the electrode metallic film in such a manner that at least two recessed portions having a depth greater than the lattice constant of crystals constituting the underlying compound semiconductor layer are present on a width direction line in any 1 μm width region of the whole surface area.

In addition, according to the present invention, there is provided a gallium nitride semiconductor device including an electrode composed of a metallic film on an underlying gallium nitride compound semiconductor layer (hereinafter referred to as underlying compound semiconductor layer), wherein

rugged portions are present dispersely over the whole surface area of the underlying compound semiconductor layer in contact with the electrode metallic film in such a manner that at least two rugged portions in which the height difference (step) between a crest portion of a projected portion constituting the rugged portion and a bottom portion of a recessed portion adjacent to the projected portion is greater than the lattice constant of crystals constituting the underlying compound semiconductor layer are present on a width direction line in any 1 μm width region of the whole surface area.

Besides, according to the present invention, there is provided a gallium nitride semiconductor device including an electrode composed of a metallic film on an underlying gallium nitride compound semiconductor layer (hereinafter referred to as underlying compound semiconductor layer), wherein

rugged portions are present dispersely over the whole surface area of the underlying compound semiconductor layer in contact with the electrode metallic film, and all the rugged portions present in any 1 μm square region of the whole surface area have an Rms (standard deviation of height) of the rugged portions of greater than 0.25 nm.

Furthermore, according to the present invention, there is provided a gallium nitride semiconductor device including an electrode composed of a metallic film on an underlying gallium nitride compound semiconductor layer (hereinafter referred to as underlying compound semiconductor layer), wherein

groove form recessed portions having a depth greater than the lattice constant of crystals constituting the underlying compound semiconductor layer and a groove width of 3 to 100 nm are present in an irregular network form at an interval of 5 to 300 nm over the whole surface area of the underlying compound semiconductor layer in contact with the electrode metallic film.

In the present invention, the gallium nitride compound semiconductor means a compound semiconductor including nitrogen (N) as a Group V element and having-a composition represented by the formula AlₐB_{b}Ga_{c}In_{d}NₓP_{y}As_{z} (wherein a+b+c+d=1; 0≦a, b, c, d≦1; x+y+z=1; 0<x≦1; and 0≦y, z≦1).

In addition, the gallium nitride semiconductor device is a semiconductor device inclusive of a light-emitting device, a light-receiving device, an electronic device, and the like in which at least a part of a compound semiconductor layer is formed of a gallium nitride compound semiconductor.

In the gallium nitride semiconductor device according to the present invention, one of the following four requirements is fulfilled for the rugged portions present in the surface of the underlying compound semiconductor layer, whereby the adhesion property between the metallic film and the underlying compound semiconductor layer is enhanced, the contact area is conspicuously enlarged, the contact resistance is largely reduced, and the metallic film enters into the recessed portions to achieve firm adhesion and attachment of the metallic film and the underlying compound semiconductor layer to each other, so that the metallic film would not easily be exfoliated from the underlying compound semiconductor layer.

(1) That recessed portions are present dispersely over the whole surface area of the underlying compound semiconductor layer in contact with the electrode metallic layer in such a manner that at least two recessed portions having a depth greater than the lattice constant of crystals constituting the underlying compound semiconductor layer are present on a width direction line in any 1 μm width region of the whole surface area.

(2) That rugged portions are present dispersely over the whole surface area of the underlying compound semiconductor layer in contact with the electrode metallic film in such a manner that at least two rugged portions in which the height difference (step) between a crest portion of a projected portion constituting the rugged portion and a bottom portion of a recessed portion adjacent to the projected portion is greater than the lattice constant of crystals constituting the underlying compound semiconductor layer are present on a width direction line in any 1 μm width region of the whole surface area.

(3) That all the rugged portions in any 1 μm square region of the whole surface area have an Rms (standard deviation of height) of rugged portions of greater than 0.25 nm.

(4) That groove form rugged portions having a depth greater than the lattice constant of crystals constituting the underlying compound semiconductor layer and a groove width of 3 to 100 nm are present in an irregular network form at an interval of 5 to 300 nm.

The present invention is applicable to a light-emitting device, a light-receiving device, an electronic device, and the like, irrespectively of the constitution of the gallium nitride semiconductor device, and, particularly, the present invention is preferably applicable to a semiconductor light-emitting device in which an underlying compound semiconductor layer is a p-type semiconductor layer, since it is possible to reduce the resistance of a p-type semiconductor layer having a high resistance.

According to the present invention, there is provided a method of producing a gallium nitride semiconductor device including an electrode composed of a metallic film on an underlying gallium nitride compound semiconductor layer (hereinafter referred to as underlying compound semiconductor layer), wherein, in growing the underlying compound semiconductor layer, the method includes the steps of:

epitaxially growing the underlying compound semiconductor layer in a predetermined film thickness at a first predetermined temperature, and thereafter lowering the temperature to a second predetermined temperature lower than the first predetermined temperature while continually introducing raw material gases for growing the underlying compound semiconductor into a film formation chamber;

maintaining the system at the second predetermined temperature for a predetermined period of time; and

subsequently stopping the supply of the raw material gases other than a nitrogen raw material gas, and lowering the temperature to room temperature while continuedly introducing the nitrogen raw material gas.

In the method according to the present invention, in the step of lowering the temperature from the first predetermined temperature to the second predetermined temperature and in the step of maintaining the system at the second predetermined temperature, the raw material gases for growing the underlying gallium nitride compound semiconductor are introduced into the film formation chamber, whereby the gallium nitride compound semiconductor is grown dispersely and microscopically over the whole surface area of the underlying compound semiconductor layer, to form rugged portions in the surface of the underlying compound semiconductor layer.

Specifically, at the time of forming the underlying gallium nitride compound semiconductor layer of GaN, the first predetermined temperature is 800 to 1050° C., the second predetermined temperature is 400 to 850° C., and the predetermined period of time is 5 to 60 sec.

According to the present invention, a method of producing a gallium nitride semiconductor device having a low operating voltage and high reliability is realized.

### BRIEF DESCRIPTION OF THE DRAWINGS

These and other objects of the invention will be seen by reference to the description, taken in connection with the accompanying drawing, in which:

FIG. 1 is a sectional view of a surface layer portion of a p-type GaN contact layer that is an underlying film for a metallic film constituting a p-side electrode of a GaN semiconductor laser device according to one embodiment of the present invention;

FIG. 2 is a sectional view showing the constitution of the GaN semiconductor laser device;

FIG. 3 is a photograph showing an outermost surface morphology of a p-type GaN contact layer that is an underlying film for a metallic film constituting a p-side electrode of a conventional GaN semiconductor laser device;

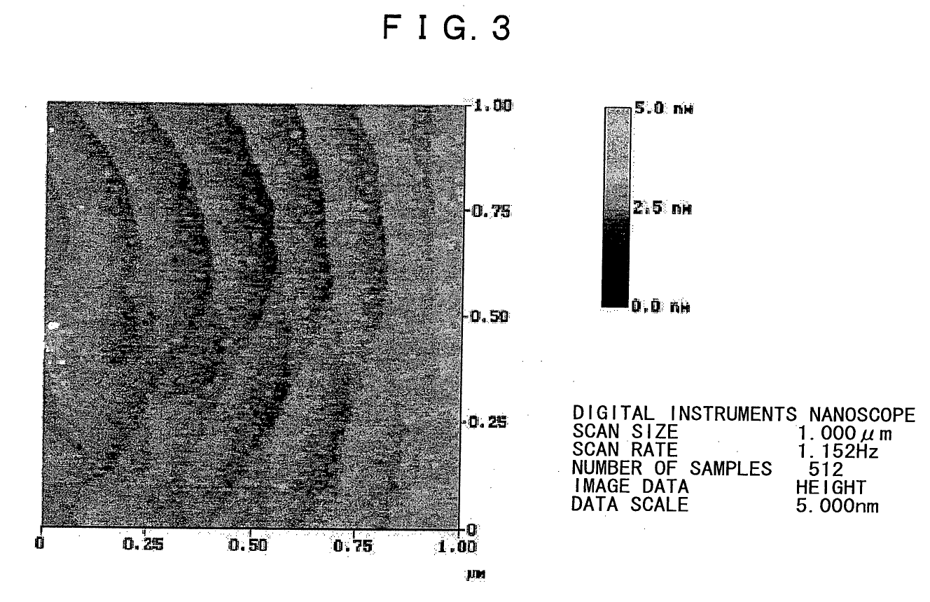

FIG. 4 is a diagram showing an outermost surface morphology of a p-type GaN contact layer that is an underlying film for a metallic film constituting a p-side electrode of a conventional GaN semiconductor laser device;

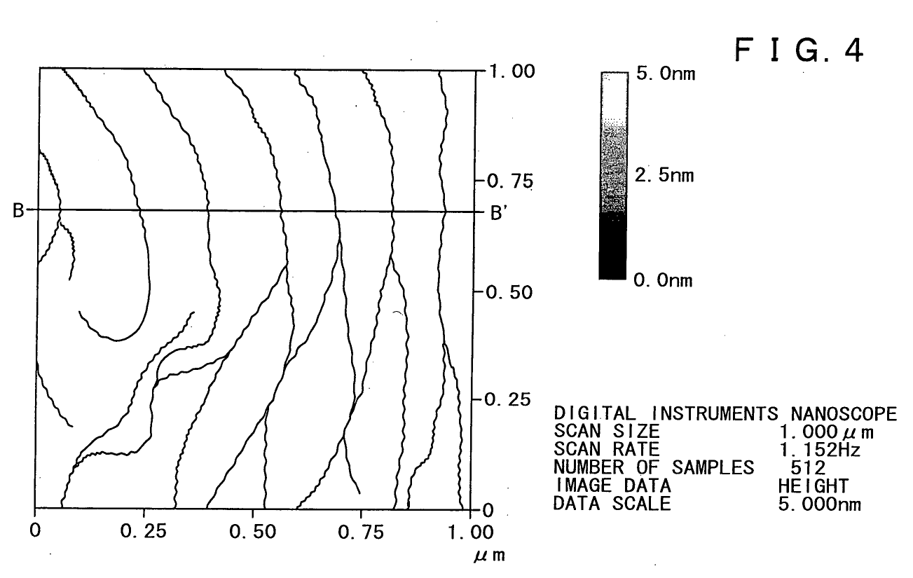

FIG. 5 is a sectional view of a surface layer portion of the p-type GaN contact layer along line B-B′ of FIG. 4 of the conventional GaN semiconductor laser' device;

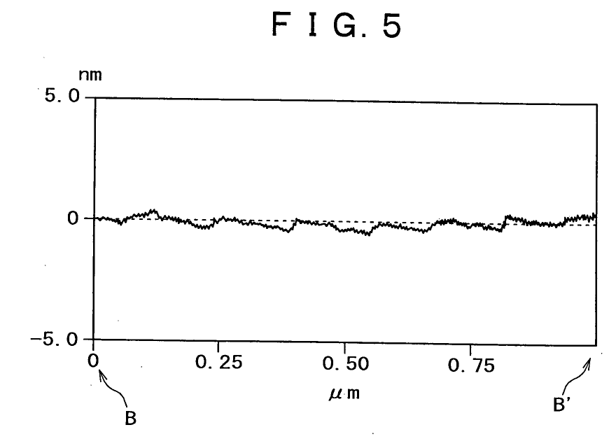

FIG. 6 is a photograph showing an outermost surface morphology of a p-type GaN contact layer according to an experimental example;

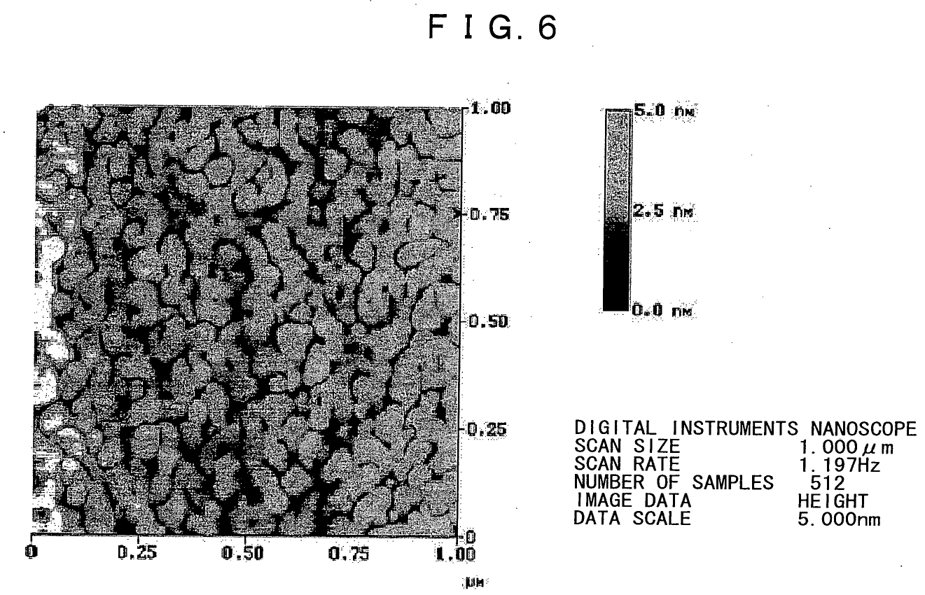

FIG. 7 is a diagram showing an outermost surface morphology of a p-type GaN contact layer according to an experimental example; and

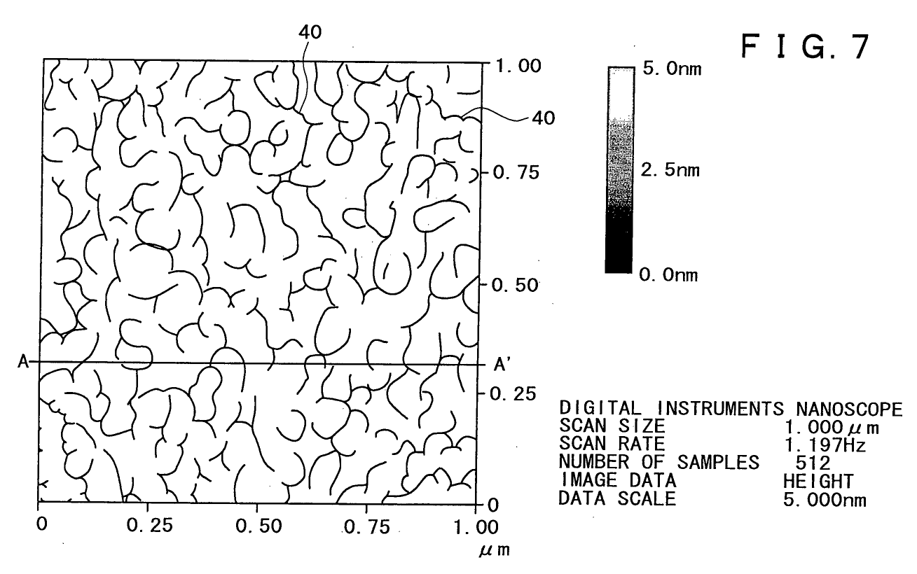

FIG. 8 is a sectional view of a surface layer portion of the p-type GaN contact layer according to the experimental example, taken along line A-A′ of FIG. 7.

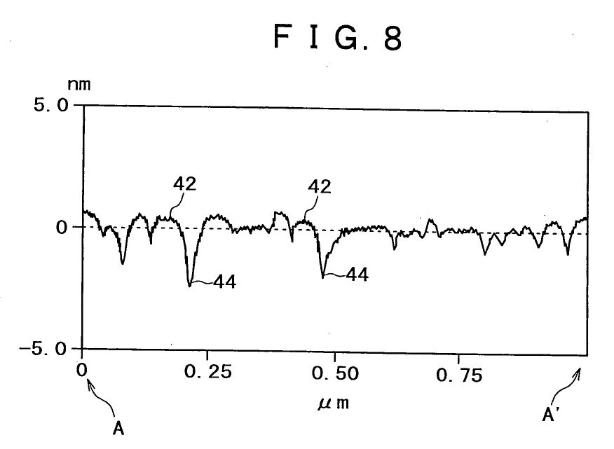

### DETAILED DESCRIPTION OF THE PREFERRED EMBODIMENTS

Now, embodiments of the present invention will be described specifically and in detail below by presenting the embodiments and referring to the accompanying drawings.

### Embodiment of Gallium Nitride Compound Semiconductor

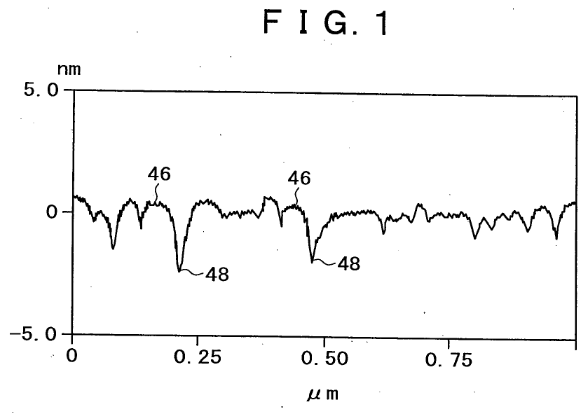

The present embodiment is one example of application of the semiconductor laser device according to the present invention to a GaN semiconductor laser device. FIG. 1 is a sectional view of a surface layer portion in a width of 1 μm of a p-type GaN contact layer, which is an underlying film for a p-side electrode metallic film in the GaN semiconductor laser device according to the present embodiment.

The GaN semiconductor laser device of the present embodiment has the same constitution as that of the above-mentioned semiconductor laser device 10, except that rugged portions are formed dispersely over the whole surface area of the p-type GaN contact layer.

The rugged portions formed over the whole surface area of the p-type GaN contact layer are present dispersely over the whole surface area of the p-type GaN contact layer in such a manner that at least two rugged portions or recessed portions are located on a width direction line in any 1 μm width region of the whole surface area, as shown in FIG. 1. The height difference (step) between a crest portion of a projected portion 46 constituting the rugged portion and a bottom portion of a recessed portion 48 adjacent to the projected portion 46 is greater than the lattice constant of the GaN crystal.

In addition, all the rugged portions present in any 1 μm square region of the whole surface area have an Rms (standard deviation of height) of the rugged portions of greater than 0.25 nm. Furthermore, groove form recessed portions having a depth greater than the lattice constant of the GaN crystal and a groove width of 3 to 100 nm are present in an irregular network form at an interval of 5 to 300 nm over the whole surface area.

In the present embodiment, due to the presence of the rugged portions, the adhesion property between the metallic film constituting the p-side electrode 36 and the p-type GaN contact layer 28 is enhanced, and the contact area is conspicuously enlarged, whereby the contact resistance is largely reduced. In addition, the metallic film enters into the recessed portions 48 to achieve firm adhesion and attachment of the metallic film and the p-type GaN contact layer 28 to each other, so that the problem of exfoliation of the metallic film from the p-type GaN contact layer 28 is obviated.

In the semiconductor laser device according to the present embodiment, the operating voltage at the time of injecting a current of 50 mA is not more than 6.0 V, which is lower by not less than 1.0 V than the operating voltage of 7.0 V of the conventional GaN semiconductor laser device 10.

### Embodiment of Production Method

The present embodiment is one example of embodiment in which the method of producing a gallium nitride semiconductor device according to the present invention is applied to the production of the above-mentioned GaN semiconductor laser device.

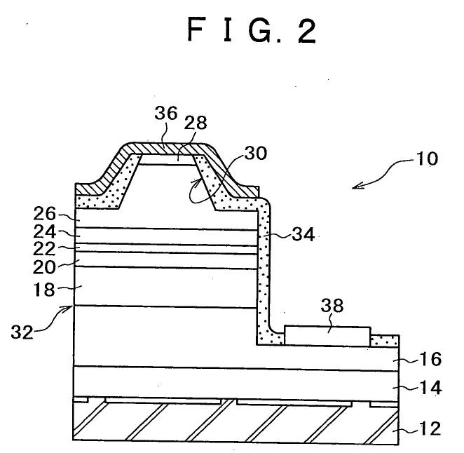

Referring to FIG. 2, the method of producing the gallium nitride semiconductor device according to the present embodiment will be described below.

By using the same materials as those in the conventional production method described above and in the same manner as above, as shown in FIG. 2, a GaN-ELO structure layer 14 is formed on a sapphire substrate 12 by applying a lateral growth method, and then an n-type GaN contact layer 16, an n-type AlGaN clad layer 18, an n-type GaN guide layer 20, and an active layer 22 composed of a GaInN multiple quantum well (MQW) structure are sequentially grown on the GaN-ELO structure layer 14 by an MOCVD method.

Further, a p-type GaN guide layer 24, a p-type AlGaN clad layer 26, and a p-type GaN layer 28 are sequentially grown.

In the formation of the laminate structure, at the time of growing the p-type GaN layer 28 after growing the p-type AlGaN clad layer 26, first, the p-type GaN layer 28 in a predetermined film thickness is grown at a substrate temperature of about 1000° C.

Next, in the present embodiment, when the growth of the p-type GaN contact layer 28 is finished, the substrate temperature is lowered from 1000° C. to 700° C. in a period of time of 1 to 2 min while continuedly supplying TMG, TMI, MeCp₂Mg, and NH₃ gas into the film formation chamber, and the system is maintained at 700° C. for 5 to 60 sec. Next, the supply of TMG, TMI, and MeCp₂Mg is stopped, and, while supplying only the NH₃ gas, the temperature is lowered to room temperature, thereby finishing the formation of the laminate structure.

Upon observation of the outermost surface morphology of the p-type GaN contact layer 28 formed as above under an AFM, it was found that groove form recessed portions having a typical depth of 1 to 2 nm were present in an irregular network form at an interval of several tens to several hundreds of nanometers over the whole surface area.

In addition, it was confirmed that rugged portions were present dispersely over the whole surface area of the p-type GaN contact layer 28 in such a manner that at least two rugged portions in which the height difference (step) between a crest portion of a projected portion constituting the rugged portion and a bottom portion of a recessed portion adjacent to the projected portion is greater than the lattice constant of the GaN crystal were present on a width direction line in any 1 μm width region of the whole surface area, and that all the rugged portions in any 1 μm square region of the whole surface area had a standard deviation of height (Rms) of the rugged portions of greater than 0.25 nm.

Next, in the same manner as in the conventional method, stripe form ridges 30 and mesas 32 are formed, and an SiO₂ film 34 is formed on both side surfaces of the ridges 30 and on the remaining layer of the p-type AlGaN clad layer 26. Subsequently, a p-side electrode 36 is provided on the p-GaN contact layer 28, whereas an n-side electrode 38 is provided on the n-GaN contact layer 16.

In this manner, it is possible to produce a GaN semiconductor laser device in which the operating voltage is low, the adhesion property and attachment property between the metallic film constituting the p-side electrode 36 and the p-type GaN contact layer are enhanced, and the p-side electrode 36 would not easily be exfoliated.

While a preferred embodiment of the invention has been described using specific terms, such description is for illustrative purposes only, and it is to be understood that changes and variations may be made without departing from the spirit or scope of the following claims.

1-7. (canceled)

8. A method of producing a gallium nitride semiconductor device comprising an electrode composed of a metallic film on an underlying gallium nitride compound semiconductor layer (hereinafter referred to as underlying compound semiconductor layer), wherein, in growing said underlying compound layer, said method comprises the steps of:
epitaxially growing said underlying compound layer in a predetermined film thickness at a first predetermined temperature, and thereafter lowering the temperature to a second predetermined temperature lower than said first predetermined temperature while continuedly introducing raw material gases for growing the underlying compound semiconductor into a film formation chamber;
maintaining the system at said second predetermined temperature for a predetermined period of time; and
subsequently stopping the supply of the raw material gases other than a nitrogen raw material gas, and lowering the temperature to room temperature while continuedly introducing said nitrogen raw material gas.

9. A method of producing a gallium nitride semiconductor device as set forth in claim 8, wherein, at the time of forming said underlying compound semiconductor layer of GaN, said first predetermined temperature is 800 to 1050° C., said second predetermined temperature is 400 to 850° C., and said predetermined period of time is 5 to 60 sec.
